(19) United States
(12) Patent Application Publication
(10) Pub. No.: US 2015/0035081 A1
(43) Pub. Date: Feb. 5, 2015

(54) INVERSE SIDE-WALL IMAGE TRANSFER

(71) Applicant: INTERNATIONAL BUSINESS MACHINES CORPORATION, Armonk, NY (US)

(72) Inventors: Kangguo Cheng, Schenectady, NY (US); Bruce B. Doris, Brewster, NY (US); Ali Khakifirooz, Mountain View, CA (US); Alexander Reznicek, Troy, NY (US)

(73) Assignee: INTERNATIONAL BUSINESS MACHINES CORPORATION, Armonk, NY (US)

(21) Appl. No.: 14/015,389

(22) Filed: Aug. 30, 2013

Related U.S. Application Data
(63) Continuation of application No. 13/956,980, filed on Aug. 1, 2013.

(51) Int. Cl. H01L 29/78

(52) U.S. Cl. CPC H01L 29/785
USPC 257/401

(57) ABSTRACT

Semiconductor devices include a set of fin field effect transistors (FETs), each having a fin structure formed from a monocrystalline substrate. A trench between fin structures of respective fin FETs is formed by a cut in the monocrystalline substrate that has a width smaller than a width of the fin structures and that penetrates less than a full depth of the monocrystalline substrate. The trenches have a width smaller than a minimum pitch of a lithographic technology employed.

### RELATED APPLICATION INFORMATION

This application is a Continuation application of co-pending U.S. patent application Ser. No. 13/956,980 filed on Aug. 1, 2013, incorporated herein by reference in its entirety.

### BACKGROUND

1. Technical Field

The present invention relates to semiconductor design, and more particularly to forming semiconductor formation by side-wall image transfer.

2. Description of the Related Art

Sidewall image transfer (SIT) provides sub-lithographic patterns by doubling the density of patterns. In conventional SIT, sidewalls are formed around one or more mandrel structures on a surface. The mandrels are then removed, leaving the sidewalls standing free on the surface. This allows the sidewalls themselves to be used to be used as a mask for further processing, allowing the creating of features with widths substantially smaller than the minimum size allowed by a given lithographic process.

However, while the conventional SIT process is well suited for producing structures that are narrower than the spacing between them (such as fin field effect transistors), in some applications structures that are wide with small spacing are more appropriate. In a conventional SIT process, the mandrels are formed using lithographic techniques and the sidewalls are substantially thinner than the space between the mandrels, such that the space between adjacent mandrels is not pinched off when the spacer material is deposited. Since spacers are used to pattern the underlying structures, conventional SIT processes can only create patterns with widths substantially smaller than the spacing.

### SUMMARY

A method for forming structures on a chip includes etching a mandrel layer that is disposed over a bottom layer to be patterned to form gaps between plateaus of mandrel material; forming spacers on sidewalls of the plateaus; forming a hardmask material in gaps between the spacers; removing the spacers to define a pattern around the hardmask material; and etching the bottom layer according to the pattern around the hardmask material.

A method for forming structures on a chip includes etching a mandrel layer that is disposed over a bottom layer to be patterned to form gaps between plateaus of mandrel material; forming spacers on sidewalls of the plateaus; forming a hardmask material that is different from the mandrel material in gaps between the spacers; forming a mask over the hardmask material with a gap over one or more regions to be cleared; etching the hardmask material under the gaps to clear the one or more hardmask regions; removing the spacers to define a pattern around the hardmask material; and etching the bottom layer according to the pattern around the hardmask material.

A semiconductor device includes a plurality of fin field effect transistors (FETs), each comprising a fin structure formed from a monocrystalline substrate, wherein a trench between fin structures of respective fin FETs is formed by a cut in the monocrystalline substrate that has a width smaller than a width of the fin structures and that penetrates less than a full depth of the monocrystalline substrate, wherein said trenches have a width smaller than a minimum pitch of a lithographic technology employed.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a diagram of a step in inverse sidewall image transfer etching in accordance with the present principles;

FIG. 2 is a diagram of a step in inverse sidewall image transfer etching in accordance with the present principles;

FIG. 3 is a diagram of a step in inverse sidewall image transfer etching in accordance with the present principles;

FIG. 4 is a diagram of a step in inverse sidewall image transfer etching in accordance with the present principles;

FIG. 5 is a diagram of a step in inverse sidewall image transfer etching in accordance with the present principles;

FIG. 6 is a diagram of a step in inverse sidewall image transfer etching in accordance with the present principles;

FIG. 7 is a diagram of a step in inverse sidewall image transfer etching in accordance with the present principles;

FIG. 8 is a diagram of a step in inverse sidewall image transfer etching in accordance with the present principles;

FIG. 9 is a diagram of a step in inverse sidewall image transfer etching in accordance with the present principles;

FIG. 10 is a diagram of a step in an alternative embodiment of inverse sidewall image transfer etching in accordance with the present principles;

FIG. 11 is a diagram of a step in an alternative embodiment of inverse sidewall image transfer etching in accordance with the present principles;

FIG. 12 is a block/flow diagram of a method for inverse sidewall image transfer etching in accordance with the present principles;

FIG. 13 is a block/flow diagram of an alternative embodiment of a method of inverse sidewall image transfer etching in accordance with the present principles; and

FIG. 14 is a top-down diagram of a set of fin field effect transistors with small pitch in accordance with the present principles.

### DETAILED DESCRIPTION OF PREFERRED EMBODIMENTS

Embodiments of the present principles provide sidewall image transfer (SIT) methods that create structures substantially wider than the spacing between them. This is accomplished by filling the spaces between the spacers with a hardmask material and removing the spacer.

In conventional SIT, sidewalls are used to block an etch, resulting in relatively small feature sizes. To accomplish this, however, the sidewalls are formed around features generated by conventional techniques, such that the spacing between the features is relatively large. The present principles invert that process by using the sidewalls to define other blocking structures. Then, instead of removing the blocking structures to allow an etch around the sidewalls, the present principles provide for the removal of the sidewalls. This allows the subsequent etch to create very small gaps between features.

In one example, where conventional lithography can produce structures having an exemplary feature size of about 80 nm, then features with a pitch down to about 40 nm can be produced. In standard SIT, the final structure is defined by spacer thickness, which needs to be thinner than half of the spacing between mandrels. An exemplary maximum width of features generated by conventional SIT process is 10-15 nm with a typical minimum spacing of 25-30 nm between the features. In contrast, an exemplary minimum width of features generated by the present principles is about 25-30 nm, having a spacing of less than about 15 nm.

It is to be understood that the present invention will be described in terms of a given illustrative architecture having a wafer; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

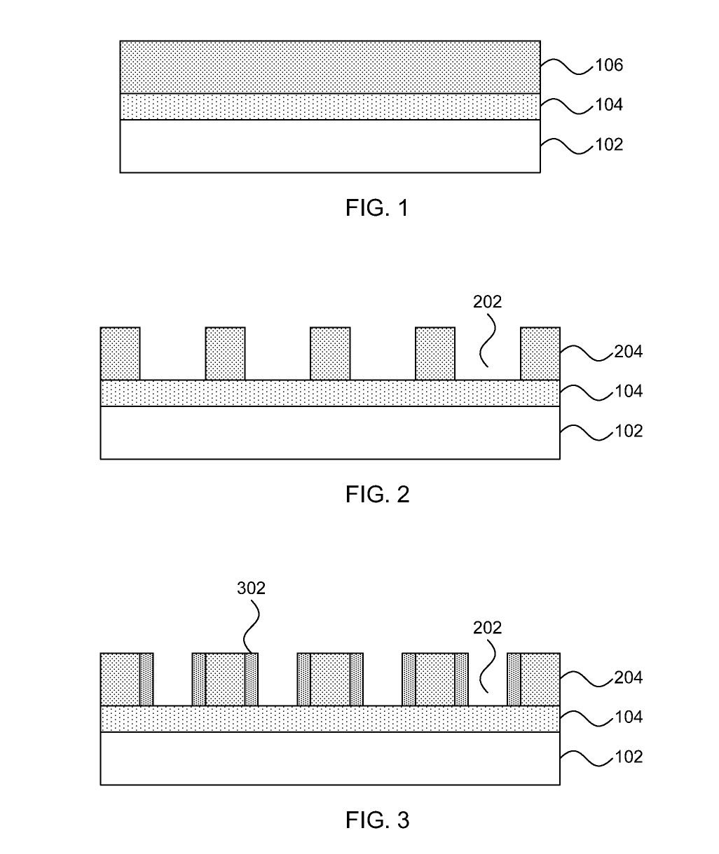

Referring now to the drawings in which like numerals represent the same or similar elements and initially to FIG. 1, a first step in forming SIT features is shown. A layer to be patterned 102 has an optional hardmask 104 over it, with a mandrel material 106 on top. The layer to be patterned may be any appropriate material including, for example, a monocrystalline semiconductor such as silicon, a silicon-on-insulator substrate, an insulator such as silicon dioxide, etc. The optional hardmask may be an appropriate hardmask material including, e.g., silicon nitride, silicon dioxide, etc. The mandrel material 106 may be formed by chemical vapor deposition (CVD) and may include, e.g., amorphous silicon or polysilicon.

Referring now to FIG. 2, a step in forming SIT features is shown. The mandrel layer 106 is patterned using photolithography and etched using an anisotropic etch such as, e.g., a reactive ion etching (RIE) process that creates spaces 202 between plateaus 204. Those having ordinary skill in the art will be able to select a suitable etch process that creates substantially vertical mandrel sidewalls and is selective to the underlying hardmask 104. Exemplary etch processes may use Cl₂, HBr, or other suitable etch processes.

Referring now to FIG. 3, a step in forming SIT features is shown. Spacers 302 are formed along the sidewalls of plateaus 204. The spacers may be formed from, e.g., a hardmask material such as silicon nitride or silicon dioxide. Spacers 302 can be formed by first depositing a conformal layer of the spacer material over the substrate, i.e. a layer with a substantially uniform thickness on both vertical and horizontal surfaces. This can be accomplished e.g. by a chemical vapor depositing process such as low pressure CVD (LPCVD), plasma enhanced CVD (PECVD), atomic layer deposition (ALD) and the like. Conformal deposition is followed by anisotropic etching of the spacer material using, e.g., an RIE process. In this manner, the spacer material deposited on the horizontal surfaces is completed etched, while the spacer material deposited on vertical sidewalls of the mandrel structure is retained. Those having ordinary skill in the art will be capable of selecting proper materials for conformal deposition and anisotropic etching of the spacer material.

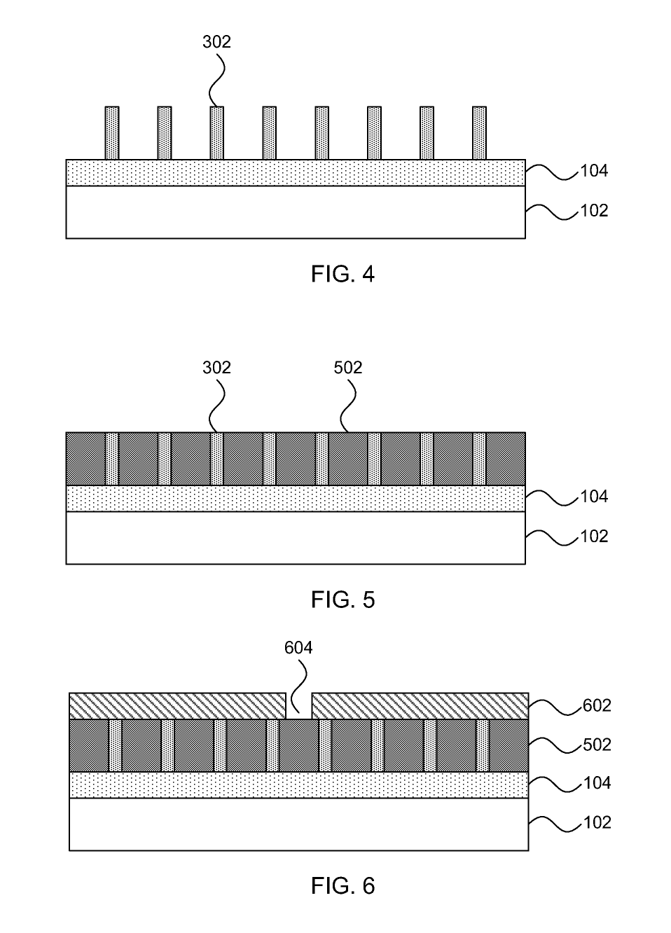

Referring now to FIG. 4, a step in forming SIT features is shown. The plateaus 204 are removed using an appropriate etch that leaves the spacers 302 untouched. This leaves the spacers 302 standing free on the optional hardmask layer 104. For example, using polysilicon as the mandrel material and silicon nitride as the spacer material, an etch process that etched polysilicon but not silicon nitride can be used, such as a wet etch using an ammonia solution.

Referring now to FIG. 5, a step in forming SIT features is shown. The gaps between spacers 302 are filled in with a hardmask material 502. The hardmask material 502 can be any material with etch selectivity with respect to the spacer material 302 and the underlying hardmask material 104. For example, if spacer material 302 is silicon nitride, the hardmask material 502 can be polysilicon deposited with a CVD process and planarized using a chemical mechanical polishing (CMP).

Referring now to FIG. 6, a step in forming SIT features is shown. A mask 602 is formed over the spacers 302 and the hardmask fill 502. A gap 604 in the mask 602 is formed over one or more of the hardmask fill regions 502. The gap 604 should be formed small enough to ensure that the mask 602 completely covers neighboring fill regions 502. SIT features can be defined using any conventional lithography processes, such as photolithography, and their position is defined by aligning a photomask to the features on the wafer.

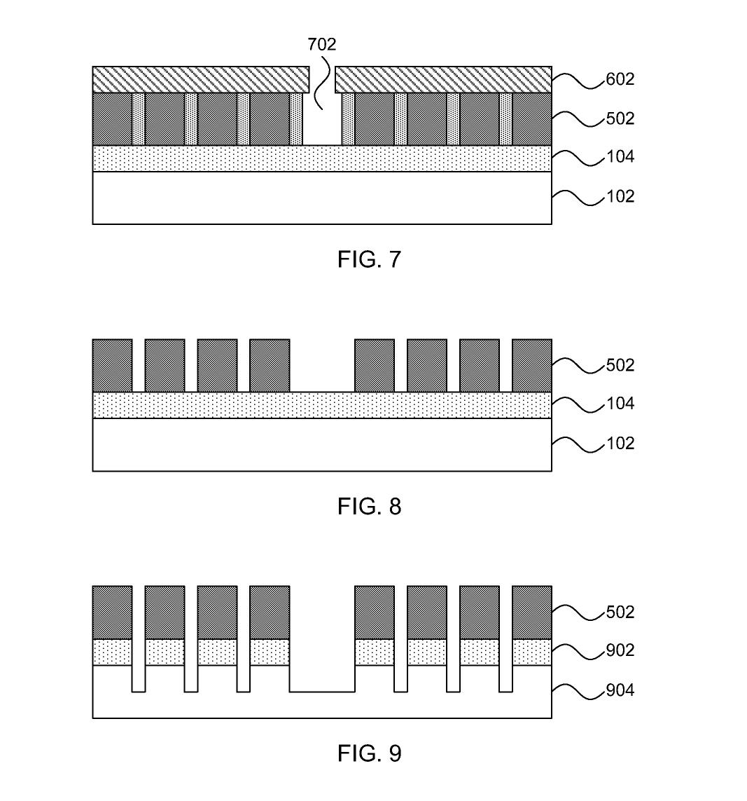

Referring now to FIG. 7, a step in forming SIT features is shown. An etch removes fill material 502 below the gap 604 in the mask 602, forming a space 702. Any wet or dry etch process capable of etching the fill material 502 and selective to the spacer material 302 can be used.

Referring now to FIG. 8, a step in forming SIT features is shown. The mask 602 and the spacers 302 are etched away, exposing the fill material 502. In the example where the spacer material 302 is silicon nitride and the fill material 502 is polysilicon, an etch process using hot phosphoric acid can be used.

Referring now to FIG. 9, a step in forming SIT features is shown. The pattern formed by the fill material 502 is transferred to the layers below by applying an anisotropic etch such as, e.g., an RIE. In an example where the hardmask is silicon dioxide, a fluorine-based RIE process, such as CF₄, can be used to transfer the patterns of the fill material 502 into the hardmask 104. This forms patterned hardmask layer 902 and patterned underling layer 904. The fill material 502 may then be removed to expose the patterned features.

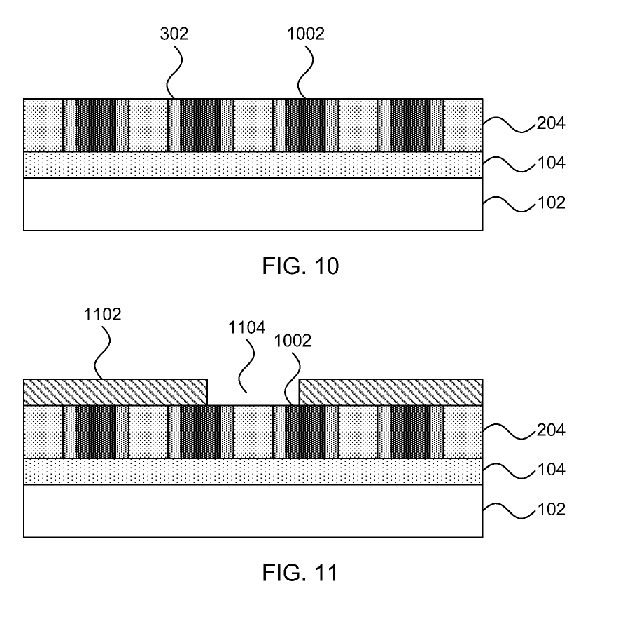

Referring now to FIG. 10, an alternative embodiment in forming SIT features is shown. This step comes after that shown in FIG. 3. A second hardmask material 1002 is deposited by, e.g., CVD and is planarized by a chemical-mechanical planarization (CMP) process that stops on the mandrel material 204 and the spacers 302. The second hardmask material 1002 is distinct from the mandrel material and should not be susceptible to the same etches. The second hardmask material 1002 is formed from, e.g., amorphous silicon-germanium.

Referring now to FIG. 11, an alternative embodiment in forming SIT features is shown. A mask 1102 is formed over the surface of the second hardmask material 1002 and the mandrel material 204. A gap 1104 formed in the mask 1102 exposes one section of mandrel material 204 but leaves other such sections covered. Because second hardmask material 1002 is different from the mandrel material 204, the gap 1104 need not be as precisely controlled and may extend over the second hardmask material 1002. An etch removes only the exposed portion of mandrel material 204.

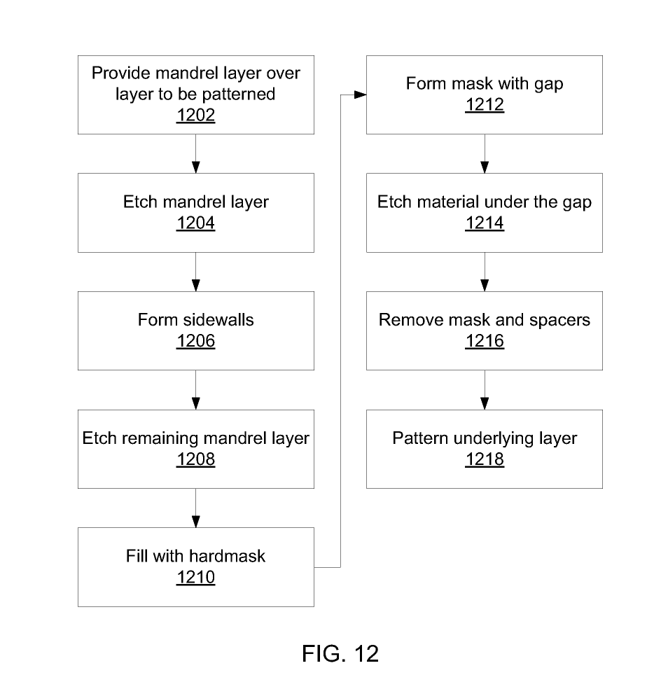

Referring now to FIG. 12, a method for forming SIT features is shown. Block 1202 provides an initial stack that includes the layer to be patterned 102 and the mandrel layer 106. Block 1204 etches the mandrel layer 106 to leave plateaus 204 of mandrel material with spaces 202 between the plateaus. Block 1206 forms spacers 302 along the sidewalls of plateaus 204 and block 1208 removes the remaining plateaus 204, leaving the spacers 302 standing free.

Block 1210 fills in the gaps between spacers 302 with a hardmask material 502. By filling in hardmask material 502 around each spacer, structures having a width considerably larger than the spacing between them can be formed using SIT. Block 1212 forms a mask 602 over the hardmask material 502, leaving a gap 604 over one region. Block 1214 etches the exposed region and leaves a gap 702. When block 1216 removes the mask 602 and the spacers 302, block 1218 etches the pattern of hardmask material 502 down to the bottom layer 102, forming a patterned layer 904.

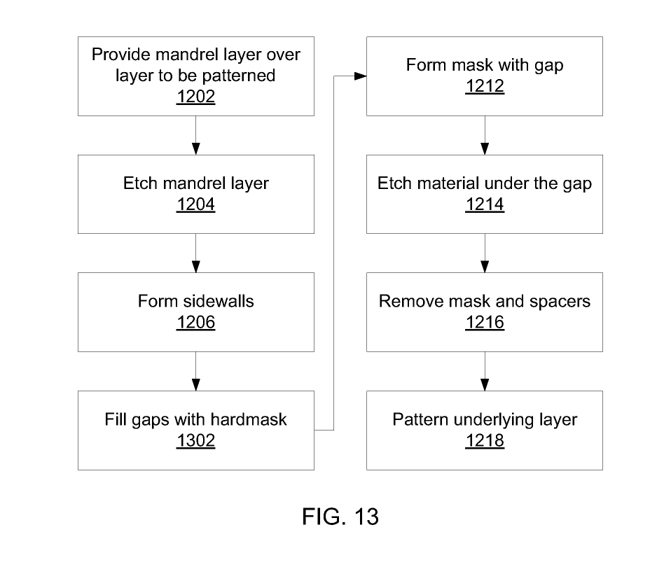

Referring now to FIG. 13, an alternative method for forming SIT features is shown. The method of FIG. 13 differs from that of FIG. 3 in that it forms hardmask material 1002 around the spacers 302 in block 1302, skipping over blocks 1208 and 1210. By separating regions of mandrel material 204 with the hardmask material 1002, the tolerances of the gap 604 need not be so tight.

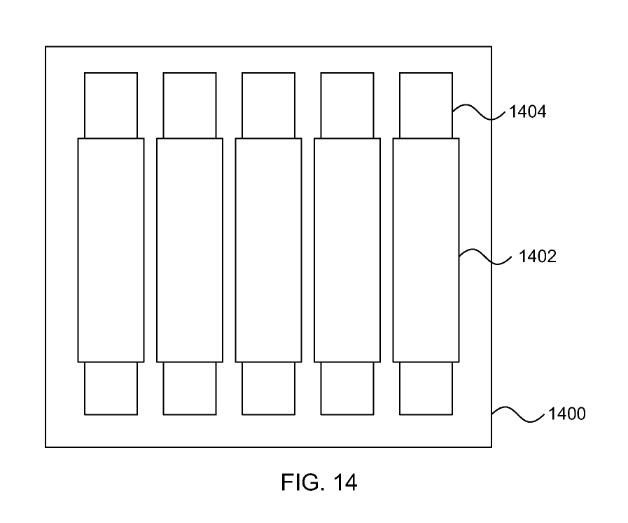

Referring now to FIG. 14, an exemplary semiconductor device 1400 is shown that includes a set of fin field effect transistors (FETs) 1402 formed with fins 1404. In devices with a strained channel, a significant performance increase is seen as the device is made narrow. When forming multiple such FETs using conventional lithography, space between the fins is wasted due to the limitations of the technology. For example, in an 80 nm channel, 40 nm is wasted in isolation. Following this example, the present principles would allow a spacing of only about 10 nm between fins 1404. This can result in a substantial performance boost in the final product, as many more FETs 1402 can be fit onto a single surface.

Having described preferred embodiments of a method for semiconductor devices and inverse side-wall image transfer methods for making the same (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device, comprising:
a plurality of fin field effect transistors (FETs), each comprising a fin structure formed from a monocrystalline substrate, wherein a trench between fin structures of respective fin FETs is formed by a cut in the monocrystalline substrate that has a width smaller than a width of the fin structures and that penetrates less than a full depth of the monocrystalline substrate, wherein said trenches have a width smaller than a minimum pitch of a lithographic technology employed.

2. The chip of claim 1, wherein the respective fin structures of the plurality of fin FETs are evenly spaced.

3. The chip of claim 1, wherein at least one fin FET in an otherwise evenly spaced set of FETs is absent, such that a gap between two adjacent fin structures is greater than a fin structure width.
